(19) United States
(12) Patent Application Publication
(10) Pub. No.: US 2014/0167058 A1
(43) Pub. Date: Jun. 19, 2014

(54) COMPOSITIONALLY GRADED NITRIDE-BASED HIGH ELECTRON MOBILITY TRANSISTOR

(71) Applicant: IQE, KC, LLC, Taunton, MA (US)

(72) Inventors: Oleg Laboutin, South Easton, MA (US); Yu Cao, Norwood, MA (US); Wayne Johnson, Easton, MA (US)

(73) Assignee: IQE, KC, LLC, Taunton, MA (US)

(21) Appl. No.: 13/973,377

(22) Filed: Aug. 22, 2013

Related U.S. Application Data
(60) Provisional application No. 61/694,014, filed on Aug. 28, 2012.

(51) Int. Cl. H01L 29/778; H01L 29/205; H01L 21/02; H01L 29/66

(52) U.S. Cl. CPC H01L 29/7783; H01L 29/66431; H01L 29/205; H01L 21/0254
USPC 257/76; 438/478

(57) ABSTRACT

An epitaxial structure on a substrate includes a gallium nitride buffer layer over the substrate and a graded channel layer over the gallium nitride layer. The graded channel layer consists essentially of InₓGa₁₋ₓN wherein the value of x gets smaller from a first surface of the channel layer proximate to a buffer layer to a second surface remote from the buffer layer.

### RELATED APPLICATION(S)

This application claims the benefit of U.S. Provisional Application No. 61/694,014, filed on Aug. 28, 2012. The entire teaching of the above application is incorporated herein by reference.

### BACKGROUND OF THE INVENTION

High electron mobility transistors (HEMTs) fabricated in a multiple-layer nitride-based semiconductor heterostructure hold great promise for high frequency, high voltage and power electronics applications due to inherent superior properties of the nitride semiconductor materials such as high breakdown field, thermal stability, and high electron mobility.

A typical prior art HEMT structure is shown in FIG. 1. It comprises a substrate 11, a nucleation layer 12 formed on the substrate, a buffer layer 13 formed over the nucleation layer, a channel layer 14 formed over the buffer layer, a spacer layer 15 formed over the channel layer and a carrier supplying barrier layer 16 formed over the spacer layer. The substrate 11 may be silicon, silicon carbide or sapphire. The nucleation layer 12 may be gallium nitride (GaN) or aluminum nitride (AlN). The buffer layer 13 is typically GaN. The channel layer 14 may be GaN or indium gallium nitride (InGaN). The spacer layer 15 is typically AlN. The barrier layer may be AlGaN or aluminum indium gallium nitride (AlInGaN). A two-dimensional electron gas (2DEG) 19 is formed inside the channel layer 14 close to the spacer layer 15.

The use of an InGaN channel layer provides an advantage of stronger 2DEG confinement compared to a GaN channel layer because potential barriers for the 2DEG are formed both at the GaN buffer/channel interface (back barrier) 18 and the channel/spacer interface 17. For the GaN channel layer, there is no back barrier.

In prior art HEMT structures with an InGaN channel, the InN mole fraction is constant in the channel layer. While a large InN molar fraction x in InₓGa₁₋ₓN is desirable for strong 2DEG confinement by the back barrier, the 2DEG mobility decreases with increasing InN molar fraction, degrading the device performance. H. Ikk, et al., Phys. Status Solid: 208, No. 7, 1614-1616 (2011).

Therefore, a need exists to overcome or minimize the above-referenced problems.

### SUMMARY OF THE INVENTION

The invention generally is directed to an epitaxial structure on a substrate and a method of making the epitaxial structure.

In one embodiment, the epitaxial structure includes a gallium nitride buffer layer over a substrate. A channel layer is over the buffer layer and consists essentially of InₓGa₁₋₁N, where 0≦x≦1, wherein the channel layer includes a 2-dimensional electron gas region distal to the buffer layer, and has a first surface proximal to the buffer layer and a second surface remote from the buffer layer, wherein the value x gets smaller from the first surface to the second surface. A barrier layer is over the channel layer.

In another embodiment, the invention is a method of forming an epitaxial structure on a substrate. The method includes forming a gallium nitride buffer layer over the substrate layer. An indium gallium nitride channel layer is formed over the gallium nitride buffer layer, the channel layer consisting essentially of InₓGa₁₋ₓN, where 0≦x≦1, wherein the channel layer includes a 2-dimensional electron gas region distal to the buffer layer, and has a first surface proximal to the buffer layer and a second surface remote from the buffer layer, wherein the value x gets smaller from the first surface to the second surface. A barrier layer is formed over the channel layer.

This invention has many advantages. For example, this invention is aimed at increasing both 2DEG confinement and mobility in a HEMT structure with the use of a graded InGaN channel layer, thereby decreasing device leakage and increasing the speed of device operation.

### BRIEF DESCRIPTION OF THE DRAWINGS

FIG. 1 is a schematic representation of typical prior art HEMT structure.

FIG. 2A is a schematic representation of a nitride-based HEMT structure of the invention.

FIG. 2B is a plot of InN and GaN mole fractions in the graded InGaN channel layer of the nitride-based HEMT structure represented in FIG. 2A.

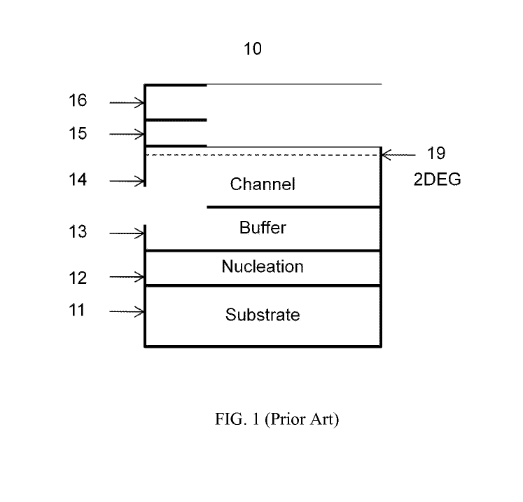

### DETAILED DESCRIPTION OF THE INVENTION

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

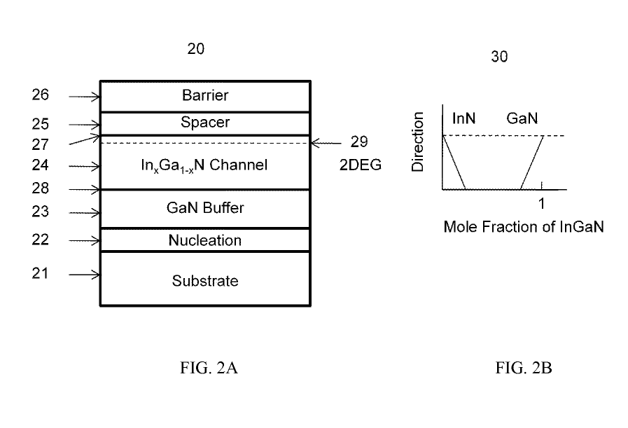

According to this invention, the HEMT structure comprises a nucleation layer 22 grown over a substrate 21, a GaN buffer layer 23 grown over the nucleation layer, an InₓGa₁₋ₓN channel layer 24 grown over the buffer layer, wherein the InN mole fraction x is decreasing in the direction from the GaN buffer layer 23 to the spacer layer 25 as shown in FIG. 2, plot 30. The preferable range of the InN molar fraction is from about 0.15 at the GaN/InGaN interface 28 to about 0 at the InGaN/AlN interface 27. In some cases, the InN molar fraction can be in the range from about 1 to about 0. The HEMT structure further comprises a spacer layer 25 grown over the InGaN channel layer, and a barrier layer 26 over the spacer layer. The spacer layer may be essentially AlN. The barrier layer may be AlGaN or AlInGaN. The source, drain and gate contacts are formed over the barrier layer 26 to fabricate a HEMT device.

Two nitride-based HEMT structures, one having a conventional InₓGa₁₋ₓN channel layer with a constant InN molar fraction x=0.06 and the other having an InₓGa₁₋ₓN channel layer with the InN molar fraction graded from about 0.12 at the GaN/InGaN interface to about 0 at the InGaN/AlN interface were grown by metal organic chemical vapor deposition (MOCVD). The InGaN channel thickness in both structures was the same, about 5 nm. The growth pressure and temperature for the channel layer were also the same, 300 Ton and 790° C., respectively. The In precursor flux was kept constant for the conventional InGaN channel with x=0.06 and ramped down linearly to 0 for the compositionally graded InGaN channel.

The transport properties of these two structures were assessed using contactless Eddy current mapping and Hall effect measurements. Table I summarizes the transport properties of the two structures. One can see that the sheet resistance and electron mobility in the HEMT structure with the graded InₓGa₁₋ₓN channel layer are superior when compared to the HEMT with the conventional InₓGa₁₋ₓN channel layer. The electron sheet density is similar in both structures.

As shown below in Table I, transport properties of the conventional InGaN-channel HEMT (36-ain-614) and compositionally graded InGaN-channel HEMT (36-ain-620) assessed using room temperature Lehighton contactless Eddy current mapping and Hall effect measurements.

TABLE 1

| | InGaN | Sheet | electron | electron |
|---|---|---|---|---|
| | channel | resistance, | density, | mobility, |
| wafer ID | composition | Ohm/sq | cm⁻² | cm²/V s |
| 36-ain-614 | constant | 319 | 2.7 × 10¹³ | 560 |
| 36-ain-620 | graded | 263 | 2.8 × 10¹³ | 640 |

The relevant teachings of all patents, published applications and references cited herein are incorporated by reference in their entirety.

While this invention has been particularly shown and described with references to example embodiments thereof, it will be understood by those skilled in the art that various changes in form and details may be made therein without departing from the scope of the invention encompassed by the appended claims.

What is claimed is:

1. An epitaxial structure on a substrate, comprising:
a) a gallium nitride buffer layer over the substrate;
b) a channel layer over the gallium nitride buffer layer,
the channel layer consisting essentially of InₓGa₁₋ₓN, where 0≦x≦1, wherein the channel layer includes a 2-dimensional electron gas region distal to the buffer layer, and having a first surface proximal to the buffer layer and a second surface remote from the buffer layer wherein the value x gets smaller from the first surface to the second surface; and
c) a barrier layer over the channel layer.

2. The epitaxial structure of claim 1, wherein the value of x varies from about 0.15 proximal to the buffer layer to about zero remote from the buffer layer.

3. The epitaxial structure of claim 1, wherein the value of x varies from about 1 proximal to the buffer layer to about zero remote from the buffer layer.

4. The epitaxial structure of claim 1, further including a spacer layer over the channel layer.

5. The epitaxial structure of claim 1, wherein the spacer layer consists essentially of aluminum nitride.

6. The epitaxial structure of claim 1, wherein the barrier layer consists essentially of indium aluminum gallium nitride.

7. The epitaxial structure of claim 1, wherein the epitaxial structure is part of a high electron mobility transistor.

8. A method of forming an epitaxial structure on a substrate, comprising the steps of:
a) forming a gallium nitride buffer layer over the substrate layer;
b) forming an indium gallium nitride channel layer over the gallium nitride buffer layer, the channel layer consisting essentially of InₓGa₁₋ₓN, where 0≦x≦1, wherein the channel layer includes a 2-dimensional electron gas region distal to the buffer layer, and having a first surface proximal to the buffer layer and a second surface remote from the buffer layer wherein the value x gets smaller from the first surface to the second surface; and
c) forming a barrier layer over the channel layer.

9. The method of claim 8, wherein the value of x varies from about 0.15 to about 0.

10. The method of claim 8, wherein the value of x varies from about 1 to about 0.

11. The method of claim 8, further including the step of forming a spacer layer over the channel layer

12. The method of claim 11, wherein the spacer layer consists essentially of aluminum nitride.

13. The method of claim 8, wherein the barrier layer consists essentially of indium aluminum gallium nitride.

14. The method of claim 11, wherein the epitaxial structure is part of a high electron mobility structure.
